(19) United States
(12) Patent Application Publication
(10) Pub. No.: US 2007/0153489 A1
(43) Pub. Date: Jul. 5, 2007

(54) COMPUTER ENCLOSURE WITH EMI SHIELDING CLIP

(75) Inventors: Chen-Lu Fan, Tu-CHENG (TW); Chieh Yang, Tu-CHENG (TW); Li-Ping Chen, Tu-CHENG (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/306,489

(22) Filed: Dec. 29, 2005

(51) Int. Cl. H05K 5/00

(52) U.S. Cl. 361/753

(57) ABSTRACT

A computer enclosure includes a chassis (10), a resilient clip (30), and a cover (50). The chassis defines at least a through hole (16). An outer surface (13) and an inner surface (15) are defined on the chassis. The cover is secured to the chassis. The resilient clip is secured to the inner surface of the chassis. At least a finger (34) is formed on the resilient clip. The finger projects from the through hole and abuts against the cover for shielding EMI. The cover is electrically contacted with the chassis through the resilient clip. Which not only further secures the cover firmly to the chassis but also prevents EMI leaking from the chassis.

### FIELD OF THE INVENTION

The present invention relates to computer enclosures, and more particularly to an computer enclosure with an electromagnetic interference (EMI) shielding clip.

### DESCRIPTION OF RELATED ART

A typical computer enclosure has many electronic components, such as disk storage and PCI cards, which are normally encased within a metal enclosure. The computer enclosure typically has removable covers. Many computer enclosures and peripherals require these removable covers to allow access to internal components for servicing or upgrading purposes. The covers, which are usually part of the “outer skin” of the computer, however, are not shielded in and of themselves. The encased electronic components are capable of conducting electromagnetic signals, which can leak out from the covers. Such electromagnetic emissions can significantly impact the performance of other electronic components, which are not within the enclosure, and components within the enclosure can be affected by the emissions of the electronic components outside the enclosure.

Thus, shielding components of highly conductive material in a sealed enclosure is necessary. One common response to this necessity is to use compliant spring fingers around the cover's perimeters to make grounding contact with the computer enclosure in order to “seal” in the electromagnetic emissions within the enclosure. The spring fingers are made of electrically conductive material, and through the use of fingers around the edges of the cover or base enclosure, grounding contact is achieved via the fingers when the cover is installed. Typically, with modern computers, numerous contact points along the perimeter of the cover are required to accomplish this task.

Another improved EMI/RFI shielding is provided for situations which require heavy duty wiping insertions, such as occurring when a relatively heavy electronic assembly is to be removably inserted in a cabinet. A plurality of EMI/RFI strips of conductive spring material are riveted to opposite cabinet walls so as to be adjacent the wiping sides of the inserted electronic assembly. Each EMI/RFI strip contains integral longitudinally spaced projecting fingers formed to provide durable and highly reliable EMI/RFI shielding capable of withstanding many insertions and removals.

However, Several basic problems arise in conventional computer systems, when providing removable covers with these spring fingers on contact points. Generally, the use of many spring fingers or strips of spring fingers require hardware or tools, such as a series of screws along the perimeter of the cover, to install. This type of installation, though arguably reliable, can be very impractical, costly, and further, it can be very time consuming for the product operator or customer during removal/installation of the covers. Additionally, because spring fingers have free ends, they are easily snagged, susceptible to damage and deformation, and can be torn off or permanently distorted if the product assembler or customer is required to frequently handle or grip the edges of the cover where the fingers are mounted. Also, because strips are extremely thin and flexible, their acute edges may produce risky conditions.

What is needed, therefore, is to provide a EMI shielding clip with a locking portion, which can be easily removed and attached.

### SUMMARY OF INVENTION

A computer enclosure includes a chassis, a resilient clip, and a cover. The chassis defines at least a through hole. An outer surface and an inner surface are defined on the chassis. The cover is secured to the chassis. The resilient clip is secured to the inner surface of the chassis. At least a finger is formed on the resilient clip. The finger projects from the through hole and abuts against the cover for shielding EMI. The cover is electrically contacted with the chassis through the resilient clip. Which not only further secures the cover firmly to the chassis but also prevents EMI leaking from the chassis.

Other advantages and novel features will be drawn from the following detailed description of a preferred embodiment with attached drawings, in which:

### BRIEF DESCRIPTION OF DRAWINGS

FIG. 1 is an assembled, isometric view of an computer enclosure of a preferred embodiment of the present invention, the enclosure including a chassis, a cover, and a resilient clip;

FIG. 2 is a partial enlarged view of the chassis of FIG. 1;

FIG. 3 is an enlarged, isometric view of the resilient clip of FIG. 1, but viewed from another aspect;

FIG. 4 is a front elevational view of the resilient clip of FIG. 1;

FIG. 5 is a right elevational view of the resilient clip of FIG. 1; and

FIG. 6 is an enlarged view of a marked elliptical portion VI of FIG. 1.

### DETAILED DESCRIPTION

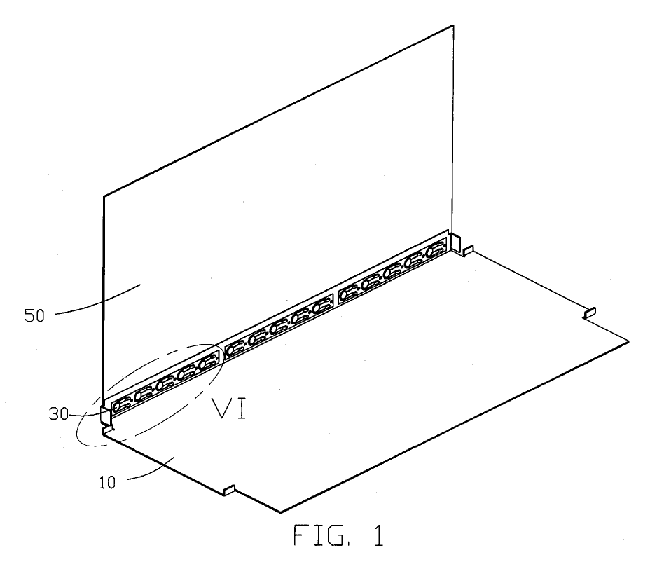

Referring to FIG. 1, an computer enclosure includes a chassis 10, a resilient clip 30, and a cover 50.

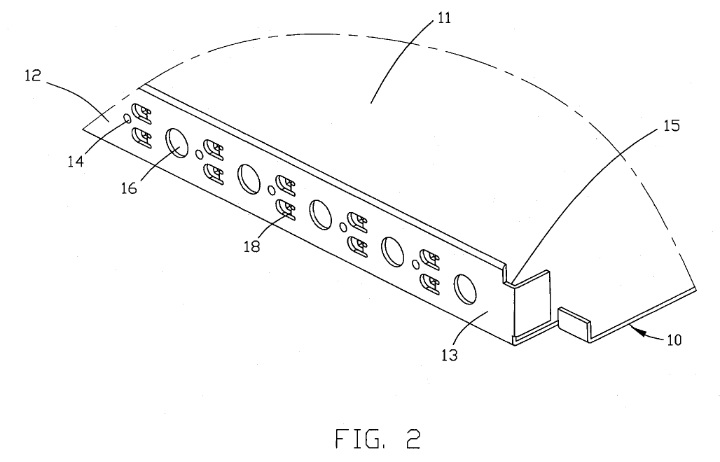

Referring also to FIG. 2, the chassis 10 includes a side panel 11. A flange 12 is perpendicularly extended from an edge of the side panel 11. The flange 12 includes an outer surface 13 and an inner surface 15. A plurality of spaced locking holes 14 is defined in the flange 12. A through hole 16 is defined in the flange 12 between each two adjacent locking holes 14. A pair of L-shaped hooks 18 is formed on the flange 12 adjacent each through hole 16.

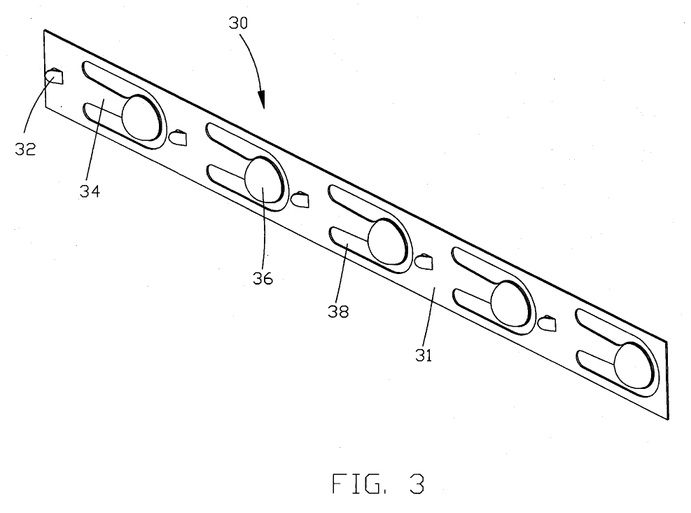

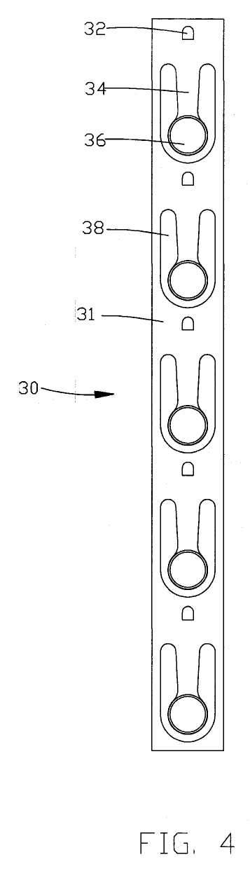

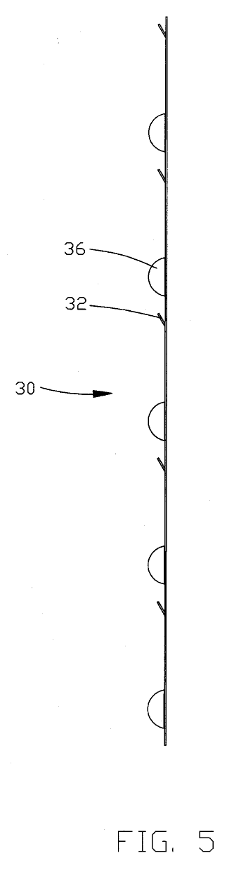

Referring also to FIG. 3 to FIG. 5, the resilient clip 30 can be resiliently deformed, and is made from electrically EMI-proof material, such as metal. The resilient clip 30 includes a strip-shaped body 31. A plurality of barbs 32 protrudes from the body 31, corresponding to the locking holes 14 of the chassis 10 respectively. A plurality of U-shaped openings 38 is punched in the resilient clip 30, between each two adjacent barbs 32. A finger 34 extends from each opening 38 of the resilient clip 30. A protrusion 36 is formed at a distal end of each finger 34, corresponding to the through hole 16 of the chassis 10, which is hemispherical but may be some other generally circle shape.

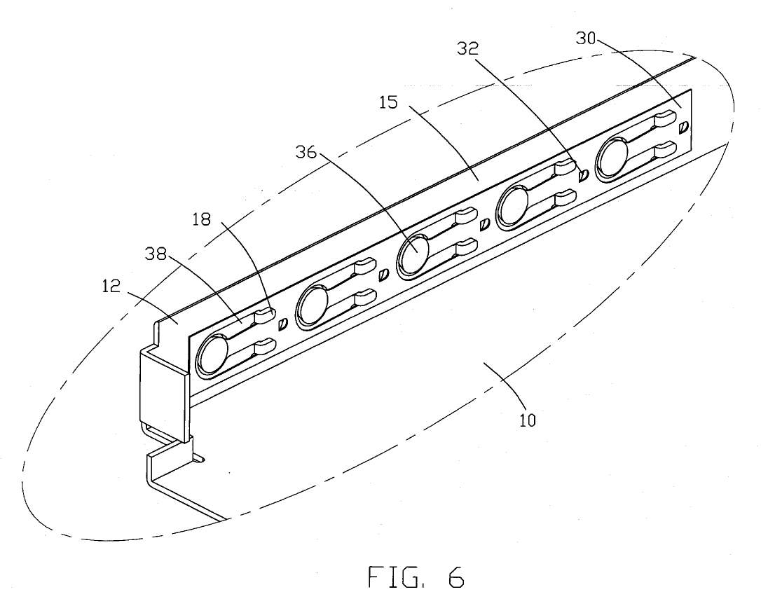

Referring also to FIG. 6, in assembling of the resilient clip 30 to the chassis 10. The resilient clip 30 is placed on the inner surface 15 of the flange 12 of the chassis 10. The hooks 18 of the chassis 10 are inserted through the corresponding openings 38 of the resilient clip 30. The barbs 32 are resiliently deformed. The resilient clip 30 is pushed to slide on the inner surface 15 of the chassis 10. When the resilient clip 30 is stopped by the hooks 18 of the chassis 10, the barbs 32 are aligned with the corresponding locking holes 14 of the chassis 10. The barbs 32 then rebound, thereby engaging into the corresponding locking holes 14 of the chassis 10. The protrusions 36 of the resilient clip 30 are aligned with the through holes 16, and engaged into the through holes 16 of the chassis 10. The resilient clip 30 cannot slide reversely. Accordingly, the resilient clip 30 is firmly secured to the chassis 10.

In assembling the cover 50 to the chassis 10, the cover 50 is positioned on the outer surface 13 of the flange 12 of the chassis 10. The cover 50 is attachably secured to the flange 12 of the chassis 10. The fingers 34 of the resilient clip 30 are respectively deformed inwardly, when the cover 50 abuts against the fingers 34 of the resilient clip 30.

The cover 50 is electrically contacted with the chassis 10 through the resilient clip 30. Which not only further secures the cover 50 firmly to the chassis 10, but also prevents EMI leaking from the chassis 10.

It is to be understood, however, that even though numerous characteristics and advantages have been set forth in the foregoing description of a preferred embodiment, together with details of the structure and function of the preferred embodiment, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A computer enclosure, comprising:
a chassis defining at least a through hole, the chassis comprising an outer surface and an inner surface;
a cover secured to the chassis; and
a resilient clip secured to the inner surface of the chassis, at least a finger formed on the resilient clip, wherein the finger projects from the through hole and abuts against the cover for shielding EMI.

2. The computer enclosure as described in claim 1, wherein a flange is bent from an edge of the chassis, and the resilient clip is secured to the flange.

3. The computer enclosure as described in claim 1, wherein the chassis comprises at least a locking hole, and at least a barb is bent from the resilient clip corresponding to the locking hole of the chassis, for engaging the resilient clip to the chassis.

4. The computer enclosure as described in claim 1, wherein a U-shaped opening is punched in the resilient clip for forming the finger thereof.

5. The computer enclosure as described in claim 4, wherein a pair of hooks is formed on the chassis for engaging in the U-shaped opening of the resilient clip.

6. The computer enclosure as described in claim 5, wherein the hooks of the chassis engage with an edge of the opening of the resilient clip.

7. The computer enclosure as described in claim 1, wherein a protrusion is formed on a distal end of the finger of the resilient clip.

8. The computer enclosure as described in claim 7, wherein the protrusion is hemispherical shaped.

9. The computer enclosure as described in claim 1, wherein the resilient clip is made of metal.

10. A computer enclosure, comprising:
a chassis defining at least a through hole;
a cover secured to the chassis; and
a resilient clip secured to the chassis, at least a finger formed on the resilient clip, and the finger having a protrusion, the protrusion protruding from the through hole of the chassis, wherein when the cover is secured to the chassis, the finger is deformed inwardly, and the protrusion abuts against the cover.

11. The computer enclosure as described in claim 10, wherein a flange is bent from an edge of the chassis, and the resilient clip is secured to the flange.

12. The computer enclosure as described in claim 11, wherein the flange of the chassis comprises an outer surface and an inner surface, and the resilient clip is secured to the inner surface of the chassis.

13. The computer enclosure as described in claim 10, wherein the chassis comprises at least a locking hole, and at least a barb is bent from the resilient clip corresponding to the locking hole of the chassis, for engaging the resilient clip to the chassis.

14. The computer enclosure as described in claim 10, wherein a U-shaped opening is punched in the resilient clip for forming the finger thereof.

15. The computer enclosure as described in claim 14, wherein a pair of hooks is formed on the chassis for engaging in the U-shaped opening of the resilient clip.

16. The computer enclosure as described in claim 10, wherein the resilient clip is strip-shaped.

17. The computer enclosure as described in claim 10, wherein the protrusion is hemispherical-shaped.
